(19) United States
(12) Patent Application Publication
(10) Pub. No.: US 2018/0151710 A1
(43) Pub. Date: May 31, 2018

(54) TRENCH GATE IGBT

(71) Applicant: ZHUZHOU CCR TIMES ELECTRIC CO., LTD., Zhuzhou (CN)

(72) Inventors: Guoyou LIU, Zhuzhou (CN); Liheng ZHU, Zhuzhou (CN); Jianwei HUANG, Zhuzhou (CN); Haihui LUO, Zhuzhou (CN); Canjian TAN, Zhuzhou (CN); Xinzhu YANG, Zhuzhou (CN); Qiang XIAO, Zhuzhou (CN); Gao WEN, Zhuzhou (CN)

(21) Appl. No.: 15/579,473

(22) PCT Filed: May 25, 2016
(86) PCT No.: PCT/CN2016/083278

§ 371 Date: Dec. 4, 2017

(30) Foreign Application Priority Data
Jan. 5, 2016 (CN) 201610003233.6

(51) Int. Cl. H01L 29/739; H01L 29/06; H01L 29/40

(52) U.S. Cl. CPC H01L 29/7397; H01L 29/407; H01L 29/0696

(57) ABSTRACT

Disclosed is a trench gate IGBT. A dummy gate is arranged between two real gates. An emitter metal is in contact with the dummy gate, so that an emitter metal contact area is not limited to an area between trenches. The emitter metal contact area includes an area where the emitter metal is in contact with the dummy gate, thereby enlarging the emitter metal contact area, and accordingly reducing a distance between each of the real gates and the dummy gate. Consequently, the distance between each of the real gates and the dummy gate is no longer affected by a minimum emitter contact area, and a turn-on voltage drop of the trench gate IGBT can be greatly reduced.

### CROSS-REFERENCE TO RELATED APPLICATIONS

This application claims the priority of Chinese patent application CN201610003233.6, entitled “Trench gate IGBT” and filed on Jan. 5, 2016, the entirety of which is incorporated herein by reference.

### FIELD OF THE INVENTION

The present disclosure relates to the technical field of semiconductor devices, and in particular, to a trench gate IGBT.

### BACKGROUND OF THE INVENTION

Currently, a trade-off relationship between a turn-on voltage drop of a trench gate IGBT (insulated gate bipolar transistor) and a blocking voltage has approached a limit. Designed structures related to reduction of the turn-on voltage drop of the trench gate IGBT include IEGT (injection enhanced gate transistor), PNM-IGBT (partially narrow mesa IGBT) and dummy gate IGBT, which improve a turn-on property of the trench gate IGBT by reducing a distance between trenches. However, in a traditional design, an emitter metal contact area can only be arranged between trenches. When trench density is increased, an emitter contact area is reduced at the same time, but the emitter contact area must be increased in order to ensure that the trench gate IGBT works safely and reliably. Therefore, there is a contradictory relationship between reducing the distance between trenches of the trench gate IGBT and increasing the emitter contact area.

FIG. 1 is a schematic diagram of a structure of the IEGT. Compared with a traditional trench gate IGBT, the IEGT reduces the turn-on voltage drop of the trench gate IGBT by reducing a distance D between trenches. However, when the distance D is reduced, an emitter ohmic contact area is also reduced at the same time, and thus a safe working area of an IGBT is narrowed. The PNM-IGBT further reduces the distance between trenches in a key area based on a distance reduction by the IEGT, and the turn-on voltage drop of the trench gate IGBT is reduced and approaches the limit. Trenches in the PNM-IGBT are formed by complicated isotropic etching.

Although a certain emitter contact area is ensured, a contradictory relationship between increasing the emitter contact area and reducing the distance between trenches still exists.

For the above trench gate IGBT, there is a contradiction between increasing the emitter contact area and reducing the distance between trenches. That is, for a trench gate IGBT in the prior art, since an emitter metal contact area is arranged between trenches, a distance between trenches is increased correspondingly at the same time when an emitter contact area is increased.

### SUMMARY OF THE INVENTION

The present disclosure provides a trench gate IGBT so as to solve a technical problem that a distance between trenches is increased correspondingly at the same time when an emitter contact area is increased for a trench gate IGBT in the prior art.

The present disclosure provides a trench gate IGBT. The trench gate IGBT comprises a semiconductor base and a first structure. The first structure comprises first trench gate structures and a second trench gate structure which are arranged at a surface interior of the semiconductor base. The second trench gate structure is arranged between two first trench gate structures. The first trench gate structures are real gates, and the second trench gate structure is a dummy gate. An emitter metal is in contact with the second trench gate structure.

In one specific embodiment, the second trench gate structure comprises a first doping area, an oxide layer which covers an inner surface of a trench, and poly-Si filled in the trench. The first doping area covers the poly-Si at an upper surface of the second trench gate structure, and a doping type of the first doping area is opposite to a doping type of the semiconductor base.

In one specific embodiment, the first structure further comprises second doping areas which are arranged within the surface interior of the semiconductor base and at sides of the first trench gate structures near the second trench gate structure and have a doping type opposite to the doping type of the first doping area, and the second doping areas are in contact with the emitter metal.

In one specific embodiment, a first trench gate structure comprises an oxide layer which covers an inner surface and an upper surface of a trench and poly-Si filled in the trench, and a passivation layer is arranged between the first trench gate structures and the emitter metal.

In one specific embodiment, the trench gate IGBT further comprises a second structure which is adjacent to the first structure. The second structure comprises third trench gate structures and a fourth trench gate structure which are arranged at the surface interior of the semiconductor base. The fourth trench gate structure is arranged between two third trench gate structures. The third trench gate structures are real gates, and the fourth trench gate structure is a dummy gate. Trenches of the first trench gate structures are in communication with trenches of the third trench gate structures, and a trench of the second trench gate structure is in communication with a trench of the fourth trench gate structure. The emitter metal is in contact with the fourth trench gate structure. The second structure further comprises third doping areas which are arranged between each of the third gate structures and the fourth trench gate structure and have a doping type opposite to the doping type of the first doping area, and the third doping areas are in contact with the emitter metal.

In one specific embodiment, the first structure further comprises fourth doping areas which are arranged within the surface interior of the semiconductor base and between each of the first trench gate structures and the second trench gate structure and have a doping type same as the doping type of the first doping area.

In one specific embodiment, a plurality of first structures and second structures are arranged, and the first structures and the second structures are arranged alternately along a direction perpendicular to a plane in which the first structures are arranged.

The present disclosure further provides a trench gate IGBT. The trench gate IGBT comprises a semiconductor base, a first trench gate structure and second trench gate structures which are arranged within a surface interior of the semiconductor base. The first trench gate structure is arranged between two second trench gate structures. The first trench gate structure is a real gate, and the second trench gate structures are dummy gates. An emitter metal is in contact with the second trench gate structures.

In one specific embodiment, the trench gate IGBT further comprises first doping areas which are arranged at sides of the first trench gate structure near the second trench gate structures and have a doping type same as a doping type of the semiconductor base, and the first doping areas are in contact with the emitter metal.

In one specific embodiment, a second trench gate structure comprises an oxide layer which covers an inner surface of a trench and poly-Si filled in the trench, and a passivation layer is arranged between the first trench gate structure and the emitter metal.

In the trench gate IGBT provided in the present disclosure, the emitter metal is in contact with the second trench gate structure/structures. That is, the emitter metal is in contact with the dummy gate/gates. In the prior art, an emitter metal contact area is arranged between trenches. However, in the present disclosure, the emitter metal contact area is not only arranged between trenches but also in contact with the dummy gate/gates. That is, the emitter metal contact area comprises an area where the emitter metal contact area is in contact with the dummy gate/gates, thereby enlarging the emitter metal contact area. By using such a structure, a distance between trenches is not increased. On the contrary, a distance between the first trench gate structures/structure and the second trench gate structure/structures can be reduced properly. In this way, a distance between the real gates/gate and the dummy gate/gates is no longer affected by a minimum emitter contact area, and a turn-on voltage drop of the trench gate IGBT can be greatly reduced. Meanwhile, a gate electrode of the dummy gate is arranged to be in contact with the emitter metal, so that the dummy gate can be connected to ground well.

Other features and advantages of the present disclosure will be further explained in the following description, and partially become self-evident therefrom, or be understood through embodiments of the present disclosure. The objectives and advantages of the present disclosure will be achieved through the structure specifically pointed out in the description, claims, and the accompanying drawings.

### BRIEF DESCRIPTION OF THE DRAWINGS

The accompanying drawings are provided for further understandings of the technical solutions of the present disclosure or the prior art, and constitute one part of the description. The drawings are used for interpreting the technical solutions of the present disclosure together with the embodiments, not for limiting the present disclosure. In the drawings:

FIG. 1 is a schematic diagram of a structure of an IEGT in the prior art;

FIG. 2 is a first schematic diagram of a structure in embodiment 1 of a trench gate IGBT in the present disclosure;

FIG. 3 is a second schematic diagram of the structure in embodiment 1 of the trench gate IGBT in the present disclosure;

FIG. 4 is a first schematic diagram of a structure in embodiment 2 of the trench gate IGBT in the present disclosure;

FIG. 5 is a second schematic diagram of the structure in embodiment 2 of the trench gate IGBT in the present disclosure;

FIG. 6 is a third schematic diagram of the structure in embodiment 2 of the trench gate IGBT in the present disclosure;

FIG. 7 is a fourth schematic diagram of the structure in embodiment 2 of the trench gate IGBT in the present disclosure; and

FIG. 8 is a schematic diagram of a structure in embodiment 3 of the trench gate IGBT in the present disclosure.

### DETAILED DESCRIPTION OF THE EMBODIMENTS

Embodiments of the present disclosure and respective features in the embodiments can be combined with one another as long as there is no conflict, and the technical solutions obtained in this manner all fall within the scope of the present disclosure. Implementing manners of the present disclosure will be explained in detail with drawings and embodiments.

### Embodiment 1

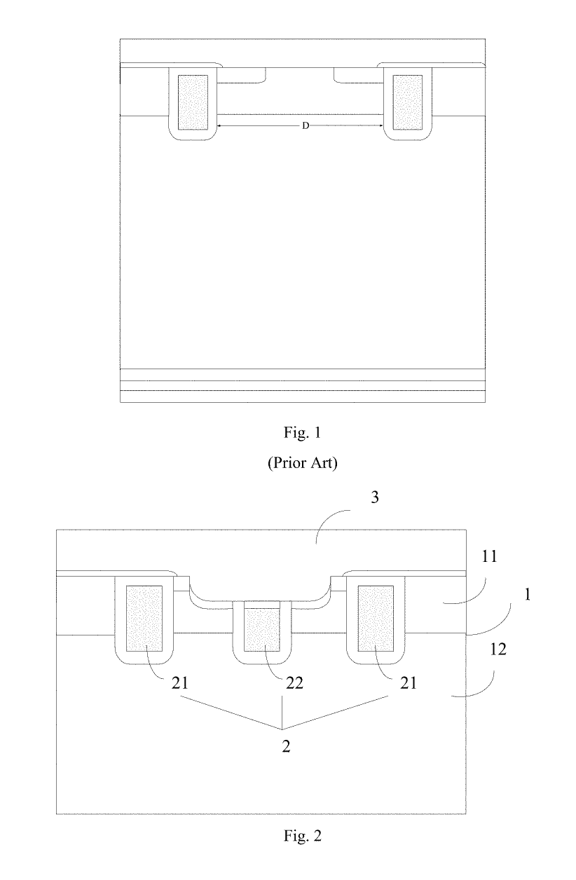

FIG. 2 is a first schematic diagram of a structure in embodiment 1 of a trench gate IGBT in the present disclosure. As shown in FIG. 2, the present embodiment provides a trench gate IGBT. The trench gate IGBT comprises a semiconductor base 1 and a first structure 2. The first structure 2 comprises first trench gate structures 21 and a second trench gate structure 22 which are arranged at a surface interior of the semiconductor base 1. The second trench gate structure 22 is arranged between two first trench gate structures 21. The first trench gate structures 21 are real gates, and the second trench gate structure 22 is a dummy gate. An emitter metal 3 is in contact with the second trench gate structure 22.

In the present description, the “surface interior of the semiconductor base 1” refers to an area that extends a certain depth from a surface of the semiconductor base 1, and the area belongs to a part of the semiconductor base 1.

The semiconductor base 1 can be made of semiconductor elements, such as silicon or silicon-germanium which has a monocrystalline, polycrystalline, or amorphous structure. The semiconductor base 1 can also be made of mixed semiconductor structures, such as silicon carbide, alloy semiconductor or a combination thereof. Limitations are not made to composition of the semiconductor base 1 herein. In the present embodiment, a silicon base is preferably used for making the semiconductor base 1, and an N-type or P-type silicon base can be used. In the present embodiment, the N-type silicon base is taken as an example for explanations.

The semiconductor base 1 comprises two parts, i.e., an N-type doping area 12 which is arranged at a bottom layer and is formed by performing an N-type doping to the semiconductor base 1, and a P-type doping area 11 which is arranged above the bottom layer and is formed by injecting P-type impurities to a surface layer of the semiconductor base 1.

The first trench gate structures 21 and the second trench gate structure 22 are U-shaped trenches, each of which has an opening arranged at an upper surface of the semiconductor base 1, penetrates the P-type doping area 11, and has a bottom arranged in the N-type doping area 12. The second trench gate structure 22 is arranged between two first trench gate structures 21, and a certain distance is kept between the second trench gate structure 22 and each of two first trench gate structures 21. The first trench gate structures 21 are real gates, and the second trench gate structure 22 is a dummy gate. A real gate refers to a gate which plays a role of control in a cell of the trench gate IGBT, and a voltage to ground of the real gate varies within a range from 15 V to −15 V. A dummy gate refers to a gate which does not play a role of control in the cell of the trench gate IGBT, and the dummy gate is usually floating or connected to ground.

The emitter metal 3 is in contact with the second trench gate structure 22. That is, the emitter metal 3 is in contact with the dummy gate. In the prior art, an emitter metal 3 contact area is arranged between trenches. However, in the present disclosure, an emitter metal contact area is not only arranged between trenches but also in contact with the dummy gate. That is, the emitter metal contact area comprises an area where the emitter metal is in contact with the dummy gate, thereby enlarging the emitter metal contact area. By using such a structure, a distance between trenches is not increased. On the contrary, a distance between each of the first trench gate structures 21 and the second trench gate structure 22 can be reduced properly. In this way, a distance between each of the real gates and the dummy gate is no longer affected by a minimum emitter contact area, and a turn-on voltage drop of the trench gate IGBT can be greatly reduced. Meanwhile, a gate electrode of the dummy gate is arranged to be in contact with the emitter metal 3, so that the dummy gate can be connected to ground well.

The above structure of the trench gate IGBT in the present embodiment is only a basic structure of a cell of the trench gate IGBT. The cell refers to a minimum repeating unit in a whole trench gate IGBT chip. That is, the trench gate IGBT provided in the present disclosure comprises a plurality of cells having the above structure.

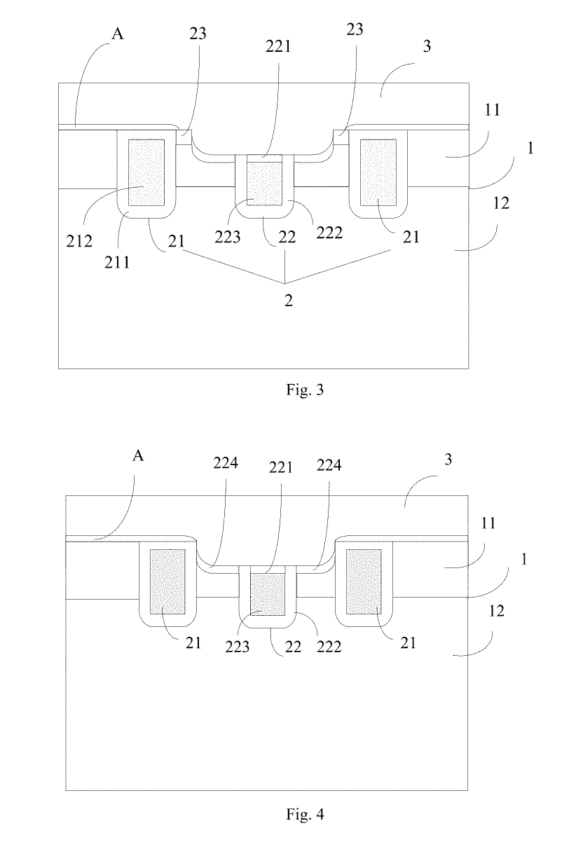

Further, FIG. 3 is a second schematic diagram of the structure in embodiment 1 of the trench gate IGBT in the present disclosure. As shown in FIG. 3, the second trench gate structure 22 comprises a first doping area 221, an oxide layer 222 which covers an inner surface of a trench, and poly-Si 223 filled in the trench. The first doping area 221 covers the poly-Si at an upper surface of the second trench gate structure 22, and a doping type of the first doping area 221 is opposite to a doping type of the semiconductor base 1.

Specifically, the oxide layer 222 which covers the inner surface of the trench can be made of silicon dioxide or silicon oxynitride. The oxide layer 222 plays a role of isolation, and can effectively isolate the poly-Si 223 filled in the trench from substances outside the trench. A gate electrode is formed by filling poly-Si in the trench. The first doping area 221 covers the poly-Si 223 at the upper surface of the second trench gate structure 22 and is in contact with the emitter metal 3, so that the dummy gate can be connected to ground well. The first doping area further covers a surface layer of the P-type doping area 11 between the real gates and the dummy gate and then is connected to the emitter metal 3 so as to form an ohmic contact.

Further, as shown in FIG. 3, the first structure 2 further comprises second doping areas 23 which are arranged within the surface interior of the semiconductor base 1 and at sides of the first trench gate structures 21 near the second trench gate structure 22 and have a doping type opposite to the doping type of the first doping area 221, and the second doping areas 23 are in contact with the emitter metal 3.

Specifically, the first structure 2 further comprises second doping areas 23. The second doping areas 23 are arranged at sides of the first trench gate structures 21 near the second trench gate structure 22, and are in contact with side walls of the first trench gate structures 21. The doping type of the second doping areas 23 is opposite to the doping type of the first doping area 221. That is, the second doping areas 23 are N-type doping areas. The second doping areas 23 are in contact with the emitter metal 3 to form source regions.

Further, as shown in FIG. 3, a first trench gate structure 21 comprises an oxide layer 211 which covers an inner surface and an upper surface of a trench and poly-Si 212 filled in the trench, and a passivation layer A is arranged between the first trench gate structures 21 and the emitter metal 3.

Specifically, the oxide layer 211 which covers the inner surface of the trench can be made of silicon dioxide or silicon oxynitride. The oxide layer 211 plays a role of isolation, and can effectively isolate the poly-Si 212 filled in the trench from the P-type doping area 11 and the N-type doping area 12. A gate electrode is formed by filling poly-Si 212 in the trench. A passivation layer A is arranged between the first trench gate structures 21 and the emitter metal 3, and the passivation layer A is configured to isolate the first trench gate structures 21 and the emitter metal 3.

A front side of the trench gate IGBT in the present embodiment is arranged according to the above manner. A back side of the trench gate IGBT in the present embodiment can be arranged in a manner in the prior art, and details will not be described herein.

### Embodiment 2

The present embodiment provides supplementation for the above embodiment.

FIG. 4 is a first schematic diagram of a structure in embodiment 2 of the trench gate IGBT in the present disclosure. As shown in FIG. 4, the present embodiment provides a trench gate IGBT. The trench gate IGBT comprises a semiconductor base 1 and a first structure 2. The first structure 2 comprises first trench gate structures 21 and a second trench gate structure 22 which are arranged at a surface interior of the semiconductor base 1. The second trench gate structure 22 is arranged between two first trench gate structures 21. The first trench gate structures 21 are real gates, and the second trench gate structure 22 is a dummy gate. An emitter metal 3 is in contact with the second trench gate structure 22.

The second trench gate structure 22 comprises a first doping area 221, an oxide layer 222 which covers an inner surface of a trench, and poly-Si 223 filled in the trench. The first doping area 221 covers the poly-Si at an upper surface of the second trench gate structure 22, and a doping type of the first doping area 221 is opposite to a doping type of the semiconductor base 1.

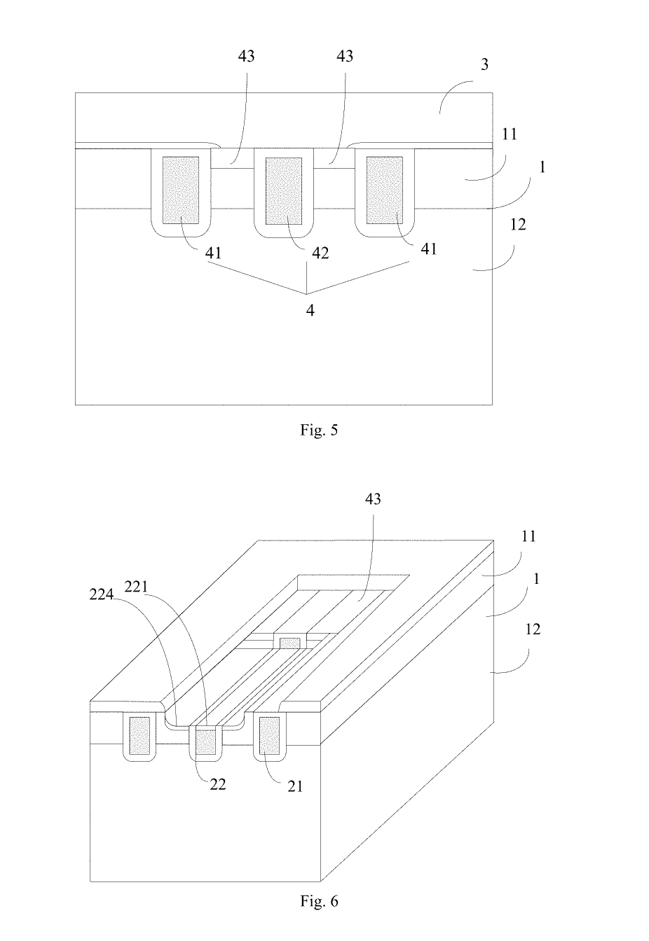

Further, FIG. 5 is a second schematic diagram of the structure in embodiment 2 of the trench gate IGBT in the present disclosure. As shown in FIG. 5, the trench gate IGBT provided in the present disclosure further comprises a second structure 4 which is adjacent to the first structure 2. The second structure 4 comprises third trench gate structures 41 and a fourth trench gate structure 42 which are arranged within the surface interior of the semiconductor base 1. The fourth trench gate structure 42 is arranged between two third trench gate structures 41. The third trench gate structures 41 are real gates, and the fourth trench gate structure 42 is a dummy gate. Trenches of the first trench gate structures 21 are in communication with trenches of the third trench gate structures 41, and a trench of the second trench gate structure 22 is in communication with a trench of the fourth trench gate structure 42. The emitter metal 3 is in contact with the fourth trench gate structure 42. The second structure 4 further comprises third doping areas 43 which are arranged within the surface interior of the semiconductor base 1 and between each of the third trench gate structures 41 and the fourth trench gate structure 42 and have a doping type opposite to the doping type of first doping area 221. The third doping areas 43 are in contact with the emitter metal 3, and an anti-latch-up capability of a trench gate IGBT cell can be improved by using such a design. Preferably, the third doping areas 43 are N-type heavy doping areas.

A three-dimensional diagram of the trench gate IGBT having the above structure is shown in FIG. 6. Preferably, a first trench gate structure 21 and a third trench gate structure 41 have a same shape and a same size, and a second trench gate structure 22 and a fourth trench gate structure 42 have a same shape and a same size.

Further, the first structure 2 further comprises fourth doping areas 224 which are arranged within the surface interior of the semiconductor base 1 and between each of the first trench gate structures 21 and the second trench gate structure 22 and have a doping type same as the doping type of the first doping areas. That is, the fourth doping areas 224 are P-type doping areas.

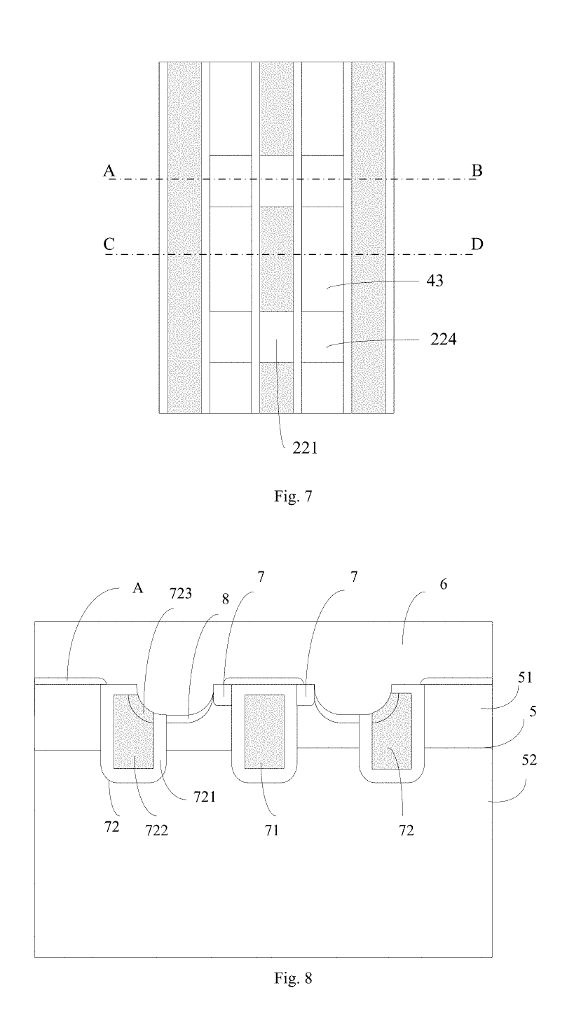

Further, FIG. 7 is a fourth schematic diagram of the structure in embodiment 2 of the trench gate IGBT in the present disclosure. FIG. 7 shows a top view of a structure of the trench gate IGBT cell of the present disclosure. A view of a cross-section AB is to shown in FIG. 4, and a view of a cross-section CD is shown in FIG. 5. Preferably, a plurality of first structures 2 and second structures 4 are arranged, and the first structures 2 and the second structures 4 are arranged alternately along a direction perpendicular to a plane in which the first structures 2 are arranged. Preferably, in a structure of one trench gate IGBT cell, a volume of the second structure 4 is twice as large as a volume of the first structure 2.

### Embodiment 3

FIG. 8 is a schematic diagram of a structure in embodiment 3 of the trench gate IGBT in the present disclosure. As shown in FIG. 8, the present embodiment provides a trench gate IGBT. The trench gate IGBT comprises a semiconductor base 5, a first trench gate structure 71 and second trench gate structures 72 which are arranged at a surface interior of the semiconductor base 5. The first trench gate structure 71 is arranged between two second trench gate structures 72. The first trench gate structure 71 is a real gate, and the second trench gate structures 72 are dummy gates. An emitter metal 6 is in contact with the second trench gate structures 72.

The semiconductor base 5 can be made of semiconductor elements, such as silicon or silicon-germanium which has a monocrystalline, polycrystalline, or amorphous structure. The semiconductor base 5 can also be made of mixed semiconductor structures, such as silicon carbide, alloy semiconductor or a combination thereof. Limitations are not made to composition of the semiconductor base 5 herein. In the present embodiment, a silicon base is preferably used for making the semiconductor base 5, and an N-type or P-type silicon base can be used. In the present embodiment, the N-type silicon base is taken as an example for explanations.

The semiconductor base 1 comprises two parts, i.e., an N-type doping area 52 which is arranged at a bottom layer and formed by performing an N-type doping to the semiconductor base 5, and a P-type doping area 51 which is arranged above the bottom layer and is formed by injecting P-type impurities to a surface layer of the semiconductor base 5.

The first trench gate structure 71 and the second trench gate structures 72 are U-shaped trenches, each of which have an opening arranged at an upper surface of the semiconductor base 5, penetrates the P-type doping area 51, and has a bottom arranged in the N-type doping area 52. The first trench gate structure 71 is arranged between two second trench gate structures 72, and a certain distance is kept between the first trench gate structure 71 and each of the two second trench gate structures 72. The first trench gate structure 71 is a real gate, and the second trench gate structures 72 are dummy gates. A real gate refers to a gate which plays a role of control in a cell of the trench gate IGBT, and a voltage to ground of the real gate varies within a range from 15 V to −15 V. A dummy gate refers to a gate which does not play a role of control in the cell of the trench gate IGBT, and the dummy gate is usually floating or connected to ground.

The emitter metal 6 is in contact with the second trench gate structures 72. That is, the emitter metal 6 is in contact with the dummy gates. In the prior art, a contact region of an emitter metal 6 is arranged between trenches. However, in the present disclosure, an emitter metal 6 contact area is not only arranged between trenches but also in contact with the dummy gates. That is, the emitter metal 6 contact area comprises an area where the emitter metal 6 is in contact with the dummy gates, thereby enlarging the emitter metal 6 contact area. By using such a structure, a distance between the first trench gate structure 71 and each of the second trench gate structures 72 can be reduced properly. In this way, a distance between the real gate and each of the dummy gates is no longer affected by a minimum emitter contact area, and a turn-on voltage drop of the trench gate IGBT can be greatly reduced. Meanwhile, gate electrodes of the dummy gates are arranged to be in contact with the emitter metal 6, so that the dummy gates can be connected to ground well.

Further, a second trench gate structure 72 comprises an oxide layer 721 which covers an inner surface of the second trench gate structure 72 and poly-Si 722 filled in a trench, and a passivation layer A is arranged between the first trench gate structure 71 and the emitter metal 6. Specifically, the inner surface of the second trench gate structure 72 is covered by the oxide layer 721. A part of an upper surface of the second trench gate structure 72 is covered by the oxide layer 721. A part of the upper surface of the second trench gate structure 72 near the first trench gate 71 is not covered by the oxide layer 721, but is covered by a second doping area 723 which has a doping type same as a doping type of the P-type doping area 51. The second doping area 723 is in contact with the emitter metal 6, thereby enlarging the emitter metal 6 contact area. Moreover, the distance between the first trench gate structure 71 and each of the second trench gate structures 72 can be reduced properly, and meanwhile the dummy gates can be connected to ground well.

Further, the trench gate IGTB provided by the present embodiment further comprises first doping areas 7 which are arranged within the surface interior of the semiconductor base 5 and at sides of the first trench gate structure 71 near the second trench gate structures 72 and have a doping type same as a doping type of the semiconductor base 5. The first doping areas 7 are in contact with the emitter metal 6.

Specifically, a first doping area is arranged at a side of the first trench gate structure 71 near a second trench gate structure 72, and is in contact with a side wall of the first trench gate structure 71. A doping type of the first doping area 7 is the same as the doping type of the semiconductor base 5. That is, the first doping area 7 is an N-type doping area. The first doping area 7 is in contact with the emitter metal 6 to form a source region. Third doping areas 8 are arranged between the first trench gate structure 71 and each of the second trench gate structures 72, and a doping type of the third doping areas 8 is opposite to the doping type of the first doping area 7.

A front side of the trench gate IGBT in the present embodiment is arranged according to the above manner. A back side of the trench gate IGBT in the present embodiment can be arranged in a manner in the prior art, and details will not be described herein.

The embodiments of the present disclosure are described only for better understanding, rather than restricting, the present disclosure. Anyone skilled in the art can make amendments to the implementing form or details without departing from the spirit or scope of the present disclosure. The patent protection scope of the present application shall be determined by the scope defined in the claims.

1. A trench gate IGBT, which comprises a semiconductor base and a first structure, wherein
the first structure comprises first trench gate structures and a second trench gate structure which are arranged at a surface interior of the semiconductor base, wherein
the second trench gate structure is arranged between two first trench gate structures; the first trench gate structures are real gates, and the second trench gate structure is a dummy gate; and an emitter metal is in contact with the second trench gate structure.

2. The trench gate IGBT according to claim 1, wherein the second trench gate structure comprises a first doping area, an oxide layer which covers an inner surface of a trench, and poly-Si filled in the trench, wherein
the first doping area covers the poly-Si at an upper surface of the second trench gate structure, and a doping type of the first doping area is opposite to a doping type of the semiconductor base.

3. The trench gate IGBT according to claim 1, wherein the first structure further comprises second doping areas which are arranged within the surface interior of the semiconductor base and at sides of the first trench gate structures near the second trench gate structure and have a doping type opposite to the doping type of the first doping area, wherein the second doping areas are in contact with the emitter metal.

4. The trench gate IGBT according to claim 1, wherein a first trench gate structure comprises an oxide layer which covers an inner surface and an upper surface of a trench and poly-Si filled in the trench, and a passivation layer is arranged between the first trench gate structure and the emitter metal.

5. The trench gate IGBT according to claim 2, further comprising a second structure which is adjacent to the first structure,
wherein the second structure comprises third trench gate structures and a fourth trench gate structure which are arranged at the surface interior of the semiconductor base,
wherein the fourth trench gate structure is arranged between two third trench gate structures; the third trench gate structures are real gates, and the fourth trench gate structure is a dummy gate; trenches of the first trench gate structures are in communication with trenches of the third trench gate structures, and a trench of the second trench gate structure is in communication with a trench of the fourth trench gate structure; and the emitter metal is in contact with the fourth trench gate structure, and
wherein the second structure further comprises third doping areas which are arranged between each of the third gate structures and the fourth trench gate structure and have a doping type opposite to the doping type of the first doping area, and the third doping areas are in contact with the emitter metal.

6. The trench gate IGBT according to claim 5, wherein the first structure further comprises fourth doping areas which are arranged within the surface interior of the semiconductor base and between each the first trench gate structures and the second trench gate structure and have a doping type same as the doping type of the first doping area.

7. The trench gate IGBT according to claim 5, wherein a plurality of first structures and second structures are arranged, and the first structures and the second structures are arranged alternately along a direction perpendicular to a plane in which the first structures are arranged.

8. A trench gate IGBT, which comprises a semiconductor base, a first trench gate structure and second trench gate structures which are arranged within a surface interior of the semiconductor base, wherein
the first trench gate structure is arranged between two second trench gate structures; the first trench gate structure is a real gate, and the second trench gate structures are dummy gates; and an emitter metal is in contact with the second trench gate structures.

9. The trench gate IGBT according to claim 8, further comprising first doping areas which are arranged at sides of the first trench gate structure near the second trench gate structures and have a doping type same as a doping type of the semiconductor base, and the first doping areas are in contact with the emitter metal.

10. The trench gate IGBT according to claim 8, wherein a second trench gate structure comprises an oxide layer which covers an inner surface of a trench and poly-Si filled in the trench, and a passivation layer is arranged between the first trench gate structure and the emitter metal.
